(19) United States
(12) Patent Application Publication
(10) Pub. No.: US 2008/0314435 A1
(43) Pub. Date: Dec. 25, 2008

(54) Nano engineered photo electrode for photoelectrochemical, photovoltaic and sensor applications

(76) Inventor: Xiaoming He, Henderson, NV (US)

Correspondence Address: ZUBER & TAILLIEU LLP, 10866 WILSHIRE BLVD., SUITE 300, LOS ANGELES, CA, 90024, US

(21) Appl. No.: 11/821,398

(22) Filed: Jun. 22, 2007

(51) Int. Cl. H01L 31/042; B05D 5/12; H01L 31/052

(52) U.S. Cl. 136/246; 136/244; 136/258; 427/74

(57) ABSTRACT

A unit nano photo cell comprised of a first component of conductive or semi conductive crystalline material, forming a backbone which spreads out in a three dimensional structural fashion, a second component of at least one photo active material bound to the first component, and a third component of carrier mobility promoter material bound to the second component, all of which together constitute a framework for separating electrons from holes when a light source is provide to the unit nano photo cell such that the second component acts as a photo active center, converting incoming photons into pairs of electron-holes, the first component transports electrons from the second component to a common bottom plate, and the third component extracts the holes from the second component and discharges them via a conductive pathway to a common top plate.

### FIELD OF THE INVENTION

The present invention relates primarily to the production of hydrogen and oxygen from water by using nano engineered photoelectrochemical (PEC) devices while harnessing solar energy. Because of similarity in fundamental energy conversion theory and practice, this invention is also suitable for applications in photovoltaic, photo sensors and imaging technologies.

### BACKGROUND OF INVENTION

Hydrogen is the most promising fuel for future energy and economy. Growing demand for low cost clean hydrogen has drawn significant attention worldwide in recent years. However, in meeting upcoming challenges, the competitiveness of existing technologies is severely diminished as a result of problems related to their expensive cost, insecurity or environmentally harmful effects.

Efficient and cost effective renewable technologies for hydrogen production hold great promise. Among these renewable approaches, hydrogen production via PEC process is the most attractive one since it generates hydrogen from water by harvesting solar energy. Despite its remarkable potential, advances in this direction have been exceptionally underperformed. So far, it has been recognized that problems associated with low Solar To Hydrogen (STH) conversion efficiency, poor device operation durability and expensive construction materials are critical limiting factors which prevent the technologies from commercialization.

United States Patent Application Publication US 2006/0100100 titled “Tetrahedrally-Bonded Oxide Semiconductors For Photoelectrochemical Hydrogen Production”. The application relates to a photocatalyst that includes a tetrahedrally-bonded oxide semiconductor. In contrast to present invention, the application is strictly limited to the use of a tetrahedrally-bonded oxide semiconductor having an energy band gap in the range of 1.5 eV to 3.2 eV. The tetrahedrally-bonded semiconductor serves as a photocatalyst for the decomposition of water. The application lacks the photoactive lattice of multiple unit nano photo cells (hereinafter referred to as UNPCs) of the present invention and does not convert water to hydrogen gas at the same level of efficiency as the present invention.

United States Patent Application Publication US 2003/0121543 titled, “Photocatalytic Film Of Iron Oxide, Electrode With Such A Photolytic Film, Method Of Producing Such Films, Photoelectrochemical Cell With The Electrode And Photoelectrochemical System With The Cell, For The Cleavage Of Water Into Hydrogen And Oxygen.” This application teaches the use of iron oxide as a photocatalytic film that when illuminated by light oxidizes water to oxygen. The application is limited to the use of iron oxide for the direct cleavage of water with visible light and poor efficiency in hydrogen production. Thus the application exhibits shortcomings overcome by the present invention.

U.S. Pat. No. 6,409,893 titled, “Photoelectrochemical Cell” teaches an electrolyte composition comprising a polymer compound formed by polymerizing an ionic liquid crystal monomer containing at least one polymerizable group. Also disclosed are an electrochemical cell, a nonaqueous secondary cell and a photoelectrochemical cell, each comprising the electrolyte composition. The patent requires in its broadest claim at least one polymerizable group, and at least one substituted or unsubstituted alkyl or alkenyl group. In contrast to the present invention, the patent is directed at teaching a novel electrolyte for use in a photoelectrochemical cell, rather than a novel 3D UNPC lattice space structure incorporated in an anode, as taught by the present invention.

Generally speaking, the prior art devices and methods described and disclosed in these above mentioned patents and publications have at least one of the following shortcomings:

Inefficient photocatalysis

Poor material interface and corrosion

Rapid hole-electron recombination

Inadequate hole mobility

Poor operational durability of devices

Expensive construction materials

Therefore, cost effective hydrogen production remains as a major issue when adopting those existing approaches. Obviously, there is a compelling and crucial need in the art for highly efficient and durable PEC devices that produce hydrogen from water under sunlight illumination.

### SUMMARY OF INVENTION

This invention provides a novel methodology that applies nano-scaled engineering to maximize STH conversion efficiency. The nano-engineered PEC anode invented in the current art improves photo current density by over ten times in magnitude when compared with technologies disclosed in the prior arts. Fundamentally, it overcomes all of aforementioned problems by nano scaled engineering.

UNPC is the key novel nano engineering concept of the present invention in maximizing STH. Each UNPC is comprised of a first component consisting of conductive or semi conductive material including photo active and inactive compositions, a second component consisting of a photo active semi conductive material or materials, and a third component consisting of a carrier mobility promoter. The second component acts as a photo active center utilizing the energy from photons to separate electrons from holes when the first component is conductive. The second component and the first component cooperate with each other to increase electron-hole separations when the first component is photo sensitive. The first component forms a backbone spreading out in a 3D structural fashion, forming a framework for UNPCs to attach on and conducts electrons when it is conductive only. The first component both conducts electrons and separates electrons from holes when it is photo sensitive. Sites having combined photo activities of component 1 and component 2 are referred to as photo active sites.

Multiple UNPCs are joined together through the first component or through the first component jointly with the second component to form a backbone, which directly contacts a conductive common bottom plate. On the opposite end, the UNPCs are linked by continuous carrier mobility promoters which lead to a common top plate. Thus, all UNPCs are bounded by a common top plate and a common bottom plate, forming a UNPC photo active mass in a Bravais lattice structural order or a hybrid structure. A nano engineered anode is formed when these multiple UNPCs are bounded by the top plate and the bottom plate in this manner.

A PEC cell basically consists of an anode, a cathode, water or an electrolyte, and a zone separator which prevents hydrogen and oxygen from mixing. When applying an adequate bias voltage, internal or external, electrons and holes from the UNPCs move into two separate flow directions, minimizing electron-hole recombination. The common top plate discharges the energy of the holes from the photo active sites into water and generates oxygen. Electrons from the photo active sites flow through the common bottom plate and feed into the cathode where water is reduced to form hydrogen gas.

Another embodiment of this invention provides advantages to fabricate flexible photo anodes such as bending photo plate anodes and fiber photo tube anodes in addition to rigid flat plates. By using the UNPC nano engineering design concept, a variety of flexible conductive substrates can be used as long as adequate nano materials can be fitted in. Fine metal woven, fiber glass and fiber glass cloth (proper coating with conductive materials) are partially transparent and flexible. It is conceivable that construction of UNPCs on these substrates achieves unique photo sensitivity or photon energy conversion efficiency suitable for powerful applications such as sensors in photonics and photovoltaic due to their potential optimum energy conversion efficiencies.

### BRIEF DESCRIPTION OF THE DRAWINGS

FIG. 1a is conceptual drawing of a UNPC 11 in accordance with a preferred embodiment of the present invention;

FIG. 1b is an illustration of the UNPC 11 structure of FIG. 1a in a monoclinic crystal system;

FIG. 2 is a generic illustration of a nanoscale engineered PEC cell in which anode 7 incorporates the UNPCs as demonstrated in FIG. 1a and FIG. 1b in accordance with a preferred embodiment of the present invention;

FIG. 3 exhibits a conceptual PV integrated nano PEC cell using anode 7 as illustrated in FIG. 2;

FIG. 4 is an illustration of a nano photo electrolyzer using anode 7 as illustrated in FIG. 2 in accordance with a preferred embodiment of the present invention;

FIG. 5 exhibits an actual test result of the current invented PEC cell as illustrated in FIG. 4 in comparison with a control (Solar Simulator: Oriel 1.6K Wl; Measurement Equipment: Keithley SourceMeter-2440, MultiMeter-2000; Program: LabTracer 2.0; Key parameters: Delay time: 1 sec; Voltage sweep: 10 mV per step, 0.0 V-1.4 V; Integration number: 1 NPLC; Temperature: Ambient; Filter: 1; Number of Steps: 141; Compliance: 100 mA; Filtering Type: Repeat; Filter Count: 10);

FIG. 6a displays a typical mapping image of carbon (C) which is incorporated in a backbone of a nano structured anode as illustrated in FIG. 2 in accordance with a preferred embodiment of the present invention;

FIG. 6b displays a typical mapping image of tungsten (W) which is incorporated in a backbone of a nano structured anode as illustrated in FIG. 2;

FIG. 6c exhibits a mapping image of sulfur (S) in component 3 which binds to photo active sites as illustrated in FIG. 1a and FIG. 1b in the anode as illustrated in FIG. 2 in accordance with a preferred embodiment of the present invention;

FIG. 6d illustrates a mapping image of fluorine (F) in component 3 in connecting with photo active sites as illustrated in FIG. 1a and FIG. 1b in the anode as illustrated in FIG. 2;

FIG. 7 shows a TEM image displaying a crystalline structure difference between component 1 and 2 in a UNPC shown in FIG. 1;

FIG. 8 demonstrates an actual monoclinic UNPC TEM image showing component 3 in contact with component 1 and 2 as illustrated in FIG. 1b

### DETAILED DESCRIPTION OF PREFERRED EMBODIMENTS

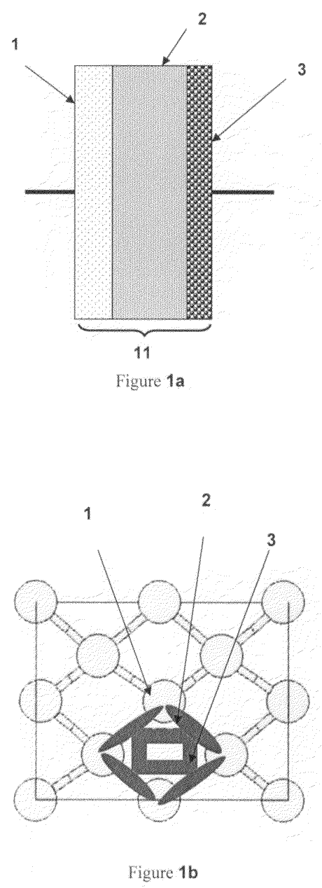

The first embodiment of the invention is the novel design of unit nano photo cell (UNPC) 11 as shown in FIG. 1a and FIG. 1b, which is preferably composed of a component 1 (semi conductive material or conductive material such as C1-doped WO₃), a component 2 (photo active semi conductive material or materials such as C2-doped WO₃, CdTe/WO₃, GaA, GaAs/WO₃ etc.) and a carrier mobility promoter 3 (Solid Polymer Electrolyte or SPE). Components 1 and 2 are different in 1) compositional or structural or 2) both compositional and structural. These differences include but are not limited to doping, physical shape and location in a UNPC. In addition, components 1 and 2 are functionally different due to their aforementioned differences. Component 1 forms backbone spreading out in a 3D structural fashion, constituting a framework of photo active film and conducting electrons while assisting separations of electrons from holes or participating separations of electrons from holes. Component 2 acts as photo active center converting incoming photons into pairs of electron-holes. In addition, components 1 and 2 may co-exist in the entire framework depending on engineering requirements and the limitations of fabrication technology. Carrier mobility promoter 3 converts holes from the photoactive component into ionic conducting species and transports the charges to a common plate where other UNPCs are linked together. Thus, electrons and holes from the UNPCs channel into two separate flow directions and minimize electron-hole recombination when an adequate bias voltage is applied internally or externally.

This invention facilitates a variety of PEC functionalities by modifying 3D structural integration of these UNPCs. The structural integration includes crystal system manipulation (triclinic, monoclinic, orthorhombic tetragonal, hexagonal, cubic), junction adjustment between: 1) the component 1 and the component 2 and 2) the component 1 and carrier mobility promoter 3 and 3) the component 2 and carrier mobility promoter 3 and junction engineering within component 2. A higher order of the backbone lattice structure may be subject to more defect issues and imposes a more stringent demand on fabrication processes. On the other hand, a lower structural order or a hybrid structure tends to provide more flexible solutions as long as they are statistically viable. Conventional characterization methodology such as porosity measurement and surface morphology may provide some sensible information regarding how the anode film surface is presented. A deeper understanding of junctions, doping and spacing in a specific UNPC, however, provides the most profound solution to the optimum efficiency of a PEC cell.

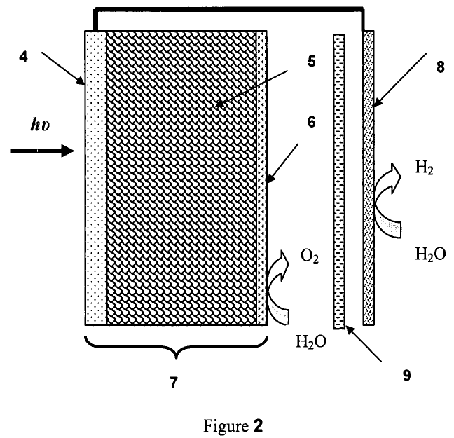

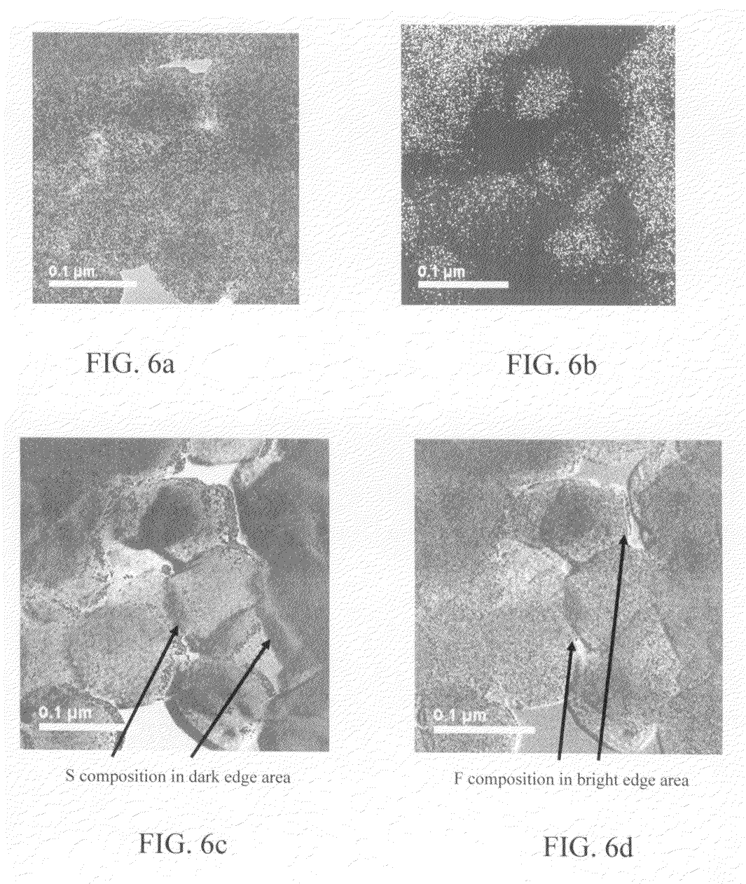

As shown in FIG. 2, anode 7 in a functional PEC cell is externally wired to make contact with cathode 8. The anode and cathode are separated by separator 9 to avoid hydrogen mixing with oxygen. In anode 7, numerous UNPCs of 11 as shown in FIG. 1 join together via a backbone component 1, or component 1 jointly with 2 forming a backbone as shown in FIG. 6a and FIG. 6b, which directly contacts a common bottom plate, a conductive film 4 consisting of transparent conductive oxide (TCO) such as indium doped tin oxide (ITO) and fluorine doped tin oxide (FTO), or metals such as Au, Ag, Ni, Ti, and Al, or any combination thereof. On the other side of anode 7, these UNPCs are linked by continuous carrier mobility promoter 3 leading towards to a common top plate 6 which directly interacts with a liquid phase such as water. Thus, all unit nano photo cells in the anode bind together in a lattice structure, all linked by a common top plate 6 and a common bottom plate 4 forming a UNPC photo active mass 5 in a Bravais lattice structural order or a hybrid formation. The top plate 6 ultimately discharges the energy of the holes from the photo active sites into water and generates oxygen. Meanwhile, electrons from the photo active sites flow into a conduction band of the backbone and, via conductive film 4, feed into cathode 8 where hydrogen is produced through reductive reaction. Depicted is the PEC processing outcome using these integrated UNPCs:

2H₂O+2e⁻=H₂+2OH⁻ (reduction at cathode)

4OH⁻═O₂+2H₂O+4e⁻ (oxidation at anode)

Or

2H⁺+2e⁻=H₂ (reduction at cathode)

2H₂O=4H⁺+O₂+4e⁻ (oxidation at anode)

Combined reaction: 2H₂O=2H₂+O₂

As can be seen, applying this top plate 6 also prevents liquid electrolytes between anode 7 and separator 9 from direct contact with photo active material and thus improves photo anode operation durability. Clearly, this invention allows broad application of materials in anode fabrication and fundamentally eliminates the corrosion issue which is one of the major road blocks in prior arts.

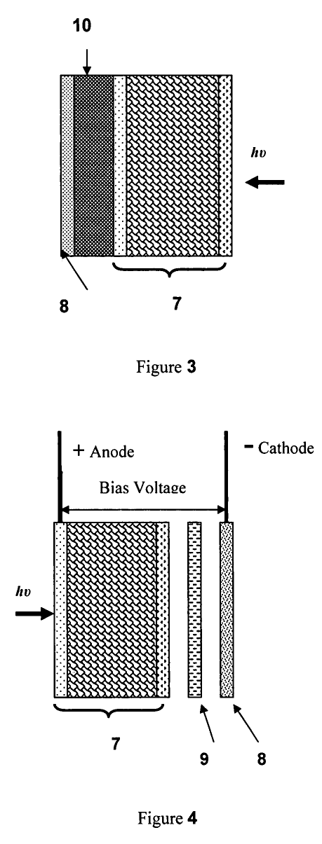

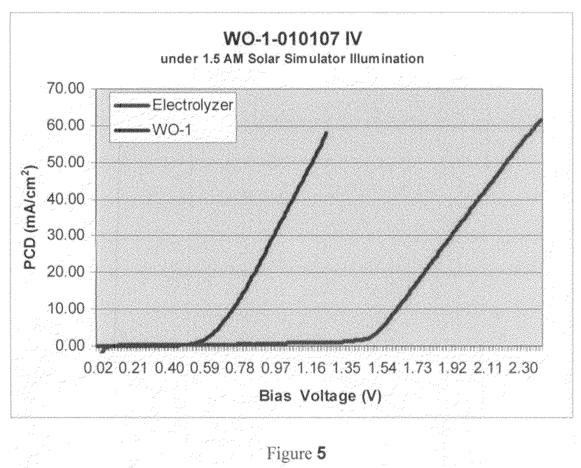

This invention is applicable to variety of PEC cell structures. As shown in FIG. 2, by incorporating multiple photo active materials in component 2 forming multi junctions, the UNPC will generate sufficient voltage to trigger water splitting and produce H₂ on the cathode and oxygen on the anode. In addition, this invention is useful in applying cell designs as shown in FIG. 3 and FIG. 4. As can be seen, the PEC cells either apply an external bias voltage or integrate an internal voltage booster. The flexibility of this currently invented art fits in a variety of prototype PEC cell designs meeting on-demand applications as needed. FIG. 3 displays a nano photo electrolyzer which applies an external bias voltage to energize the PEC operation in addition to direct solar irradiation. This assisted water splitting PEC process is a much more cost effective approach in comparison with PV or grid line supported electrolysis. Component 10 in FIG. 4, on the other hand, is a film stack consisting of multiple PV junctions creating an internal bias voltage. In this case, all consumed energy originates from solar irradiation. Because of the high PEC conversion efficiency of this invention, both water splitting systems become cost competitive and viable for large scale applications. As shown in FIG. 5, this currently invented nano PEC device produces much higher photo current density than the control, the one which dose not have UNPCs in anode.

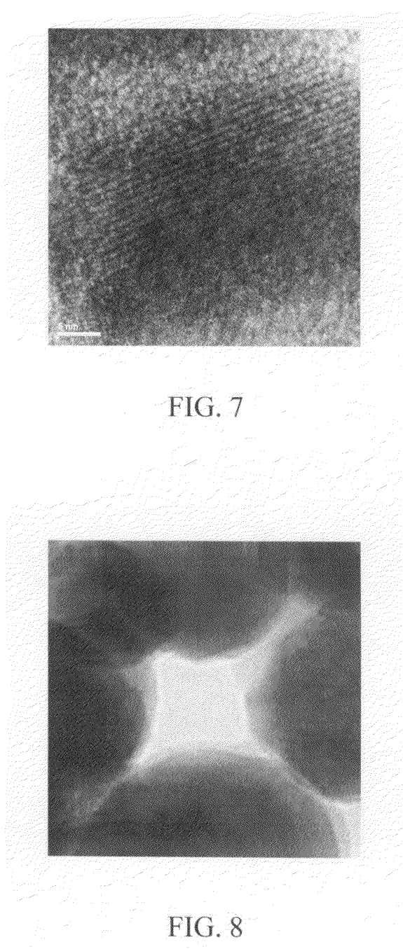

Referring again to FIG. 1, construction of materials 1 and 2 falls into two categories. One category covers materials that exhibit a distinguished crystalline structural difference between these two components as shown in FIG. 7. The other includes materials which display a continuous structural extension with compositional variation across the center of the material to the very edge at nano scale. In the later case, components 1 and 2 are so intimately bounded together that a physical boundary can be visualized only at subnano scale.

It is conceivable that a variety of materials can be deployed to fabricate UNPC based PEC anodes, photovoltaic film stacks and sensor electrodes. This invention includes but is not limited to the following material systems: Fe₂O₃ with SiO₂ doping; WO₃ with carbon doping; TiO₂/Ti; CdS with doped Si; CdTe/WO₃; GaAs with doped Si; GaAs/WO₃; TiO₂/Fe₂O₃; InP; CuInSe₂; copper indium gallium diselenide (CIGS) or variations and combinations thereof.

### Construction Materials for Carrier Mobility Promoter 3

Solid Polymer Electrolyte such as Surlyn and Nafion etc. are good materials to serve as component 3 in the UNPCs as illustrated in FIG. 6c and FIG. 6d. One example of these materials is polyethylene-co-methacrylic acid. This polymer is a sodium or zinc salt (which provides the ions) of copolymers derived from ethylene and methacrylic acid. Sulfonated tetrafluorethylene copolymer is another example of the SPE which is commercially available and durable, therefore suitable for the applications. Due to its good conductivity, this material has demonstrated powerful performance and is commercially viable for large scale operations.

Other ionomers including polymeric electrolytes such as lithium poly(2-sulphoethyl methacrylate, sodium poly(phosphazene sulphonate), poly-diallydimethylammonium chloride and sodium polystyrene sulphonate are good to serve as component 3 if a proper treatment is received prior to applying for the UNPC application.

It is conceivable that proper carrier promoters can be deployed to fit photovoltaic and sensor electrode applications based on UNPC design concept Materials with conductivity dominantly attributed to n-doping, such as silicon doped with P or As, may serve as a promoter after applying adequate surface treatment for PV and sensor electrode applications.

Anode 7 construction includes but not limited by the following steps:

1. Bottom Plate 4 Preparation
This step requires a surface treatment for a desired conductive substrate such as TCO (ITO or FTO) or metallic conductive materials (Al, Ti, Ni, Ag, Au etc.) with a cleaning process to remove any inadequate surface species or with a surface preparation process to construct a proper topography prior to receiving photoactive materials. For example, a transparent conductive material FTO is rinsed with deionized water, acetone and then ultrasonically cleaned in an ethanol bath for five minutes. This is followed by air dry under ambient condition.

2. Crystalline Material Growth
Construction of components 1 and 2 depends on process control which has to do with but not limited to deposition rate, temperature control and post annealing treatment. Precursors for Fe₂O₃, TiO₂, WO₃, CdS, GaAs, etc. are prepared in such a way that they fit whatever a specific process requires. Clear solution or slurry or colloidal dispersion of a desired material precursor are suitable for the film constructions via processes such as crystallization in a homogeneous solution, roller and spin-on coating with heterogeneous slurry or a colloidal dispersion, spray vaporization and spray pyrolysis using dissolved salts. In addition, dry raw materials are also useful precursors applicable for MOCVD (metallic organo chemical vapor deposition), CVD (chemical vapor deposition), APCVD (Atmosphere pressure chemical vapor deposition), PECVD (plasma enhanced chemical vapor deposition), ALD (atomic layer deposition), and PVD (physical vapor deposition). Moreover, electrochemical processes such as plating and anodization can be good processes if the selections of photo sensitive materials are favorable for those approaches. In a typical case, a layer (50 μM) of 0.5M colloidal dispersion of tungstic acid in a mixture solvent (H₂O>90%, ethanol <2%, polyethylene glycol <8%) is applied to a clean common bottom plate 4 by roller coating techniques or a spin-on coating process. This is followed by a heating process at a temperature ramp rate of 5° C. per minute to heat up to 500° C. After cooling down to ambient condition, a second layer is applied in the same manner. Once three or four layers of this material are applied, the anodic backbone is preliminary constructed.

3. Photo Activity Enhancement
As a simple application for the enhancement of component 2 performance, this step utilizes an annealing process with a reactive reagent or under vacuum or under an inert environment. In this case, the annealing temperature and time are the primary factors to control the surface performance. When comes to construct a multi junction component 2, more complicated processes such as CVD and PVD are used to serve the purpose. A simple example of this step operation is oxygen reactive annealing for WO₃ performance enhancement In order to optimize the photo activity, a two hour annealing at 550° C. in the presence of oxygen is generally required.

4. Top Down Capsulation
Generally speaking, component 3 is deposited after components 1 and 2 are constructed. The addition of this third component may receive a process which allows the desired material to bind the nano scaled sites consisting of component 1 and 2. Therefore, a dry coating process with a melted solid electrolyte or molten salt at an elevated temperature, or a condensation process under low vapor pressure of a selected precursor, or a surface binding process by adding a solution of a selected precursor or a combination of these aforementioned processes is applied to coat the component 3 onto the framework consisting of components 1 and 2. Post treatment includes but is not limited to vaporization, concentration, curing, annealing, cooling and drying. The preferred process temperature for component 3 is lower than 150° C. when a SPE is used and 550° C. for molten salt. The preferred thickness of the coated component 3 is greater than 1 nm. The preferred working ionic conductivity is better than 1 Ω/□.

### PEC Cell Construction

A PEC cell set-up depends on whether an external bias voltage is required. As shown in FIG. 3, the gap distance between cathode 8 (such as Pt or Pt coated metallic or non-metallic materials) and anode 7 is not a significant factor for a PEC cell to perform at its optimum capacity. However, the PEC cell as displayed in FIG. 4 is highly subjective to a number of factors such as gap filler (water or aqueous electrolyte), separator 9 which is a water permissive material such as ultra fine mesh ploy propylene, and gap distance between 7 and 8. These factors require special engineering work to optimize the PEC performance based on specific anodic materials. A gap distance less than 50 μm for conducting a PEC process with an aqueous electrolyte is preferred and a gap distance less than 25 μm is preferred to operate PEC process with pure water having a resistivity greater than 1 MΩ.

### EXAMPLE 1

An example of the nano-engineered PEC anode of stack 7 in FIG. 4 is F—SnO/C—WO₃-Nafion. The bias voltage applied can be set at a value lower than 1.2V for continuous solar simulator or sunlight operation. Scanning bias voltage in a range of 0-1.4V is used for PEC I-V data collection under 1.5 AM standard solar irradiation condition. In one specific embodiment, the structure of the assembled PEC cell using the nano engineered photo electro anode comprises:

glass//F—SnO/C—WO₃-Nafion/thin porous film/Pt gauze.

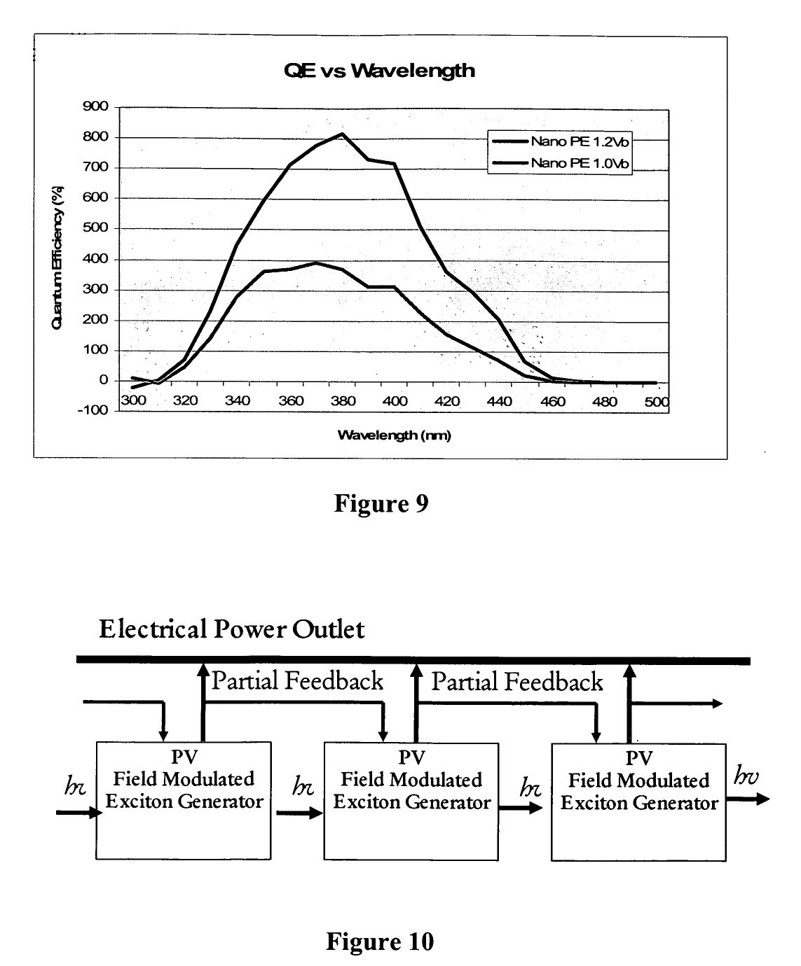

The thicknesses of the respective layers are approximately: 2 mm/2μ/4μ/10 μm/200 μm, respectively, for optimum sunlight or solar simulator illumination. More specifically, the fine structure of the UNPC in stack 7 shows nano crystalline photo active sites whose sizes are in the range of 20000-125000 nm³ and dimensions on each side are in the range of 25-50 nm. They are directly in contact with a layer of 2-6 nm carrier mobility promoters as demonstrated in FIG. 8.

In certain specific embodiments, the film thickness, density and crystalline size of WO₃ may be adjusted such that an optimum balance of backbone and promoter can be reached. For maximum photon capture, for example, the thickness of WO₃ layer needs to be thick enough to allow a zero transmission for photons with wave length shorter 490 nm.

In certain embodiments, the PEC cell deploys metal substrates such as Ni, Ti and Al or metal grids, such as Ag and Au grids, supported conductive glass. Woven mesh, cloth and sheets are desirable to achieve special conductivity and structure and thus minimize resistive loss of conversion efficiency.

There are different PEC materials which can be deployed in a similar nano engineered fashion as aforementioned. One of the direct extensions of this UNPC is to apply Fe₂O₃, TiO₂, WO₃, CdS, CdTe, GaAs, etc for water splitting PEC processes. In addition to the methods described above, another way to optimize cell performance is to apply basic electrolytes such as aqueous solutions of NaOH, KOH or acidic electrolytes such as aqueous solutions of H₂SO₄ in addition to applying a SPE.

In such embodiments, flow dynamic processes can be used in a way that water or aqueous electrolytes can flow directly into the cell by applying mechanical or thermal transport means instead of bubbling in a static PEC cell.

### EXAMPLE 2

Application of the nano engineered PEC anode on photovoltaic electrode is another embodiment of the current invention as shown in FIG. 3. This application integrates at least one of the following solar cell types: copper indium diselenide (CuInSe₂), copper indium gallium diselenide (CIGS), amorphous silicon (a-Si), III-V (GaAs, InP etc), cadmium telluride (CdTe), crystalline silicon (c-Si), thin film silicon (thin-Si), or variations and combinations thereof. Furthermore, in certain embodiments, the integrated PEC photovoltaic electrode has multiple junctions including two junctions, three junctions and more junctions wherein sufficient voltage is generated for solar to hydrogen conversion.

The above detailed description of the present invention is given for explanatory purposes. It should be understood that all references cited herein are expressly incorporated herein by reference. It will be apparent to those skilled in the art that numerous changes and modifications can be made without departing from the scope of the invention. Hence, the whole of the foregoing description is to be construed in an illustrative and not a limitative sense, the scope of the invention being defined solely by the appended claims.

1. A unit nano photo cell comprising:
a first component of conductive or semi conductive crystalline material, forming a backbone which spreads out in a three dimensional structural fashion;
a second component of at least one photo active material bound to the first component; and
a third component of carrier mobility promoter material bound to the second component;
together all of which constitute a framework for separating electrons from holes when a light source is provided to the unit nano photo cell.

2. The unit nano photo cell of claim 1, wherein the second component acts as a photo active center, converting incoming photons into pairs of electron-holes when a light source is provided to the unit nano photo cell.

3. The unit nano photo cell of claim 1, wherein the first component of conductive or semi conductive crystalline material transports electrons from the second component of at least one photo active material to a common bottom plate when a light source is provided to the unit nano photo cell.

4. The unit nano photo cell of claim 1, wherein, the first component of conductive or semi conductive crystalline material is photosensitive and further wherein the first component of conductive or semi conductive material participates in separating electrons from holes in addition to transporting electrons from the second component when a light source is provided to the unit nano photo cell.

5. The unit nano photo cell of claim 1, wherein the third component of carrier mobility promoter material converts holes from the second component into ionic conducting species or charges and transports them to a common top plate when a light source is provided to the photo active material or materials of the unit nano photo cell.

6. The unit nano photo cell of claim 1, wherein the third component of carrier mobility promoter material is a conductive material such as solid polymer electrolyte (SPE) capable of extracting the holes from the second component and discharging the energy of the holes via a conductivity pathway.

7. A nano-engineered anode for use in a photoelectrical chemical (PEC) cell comprising:
a plurality of unit nano photo cells joined together and forming a nano structured framework;
an ionic conductive common top plate coupled to the nano structured framework; and
a conductive common bottom plate coupled to the nano structured framework,
thereby forming a photo active mass in a 3D lattice fashion or a hybrid crystalline structure, transporting electrons from the plurality of unit nano photo cells to the common bottom plate and transporting holes from the plurality of unit nano photo cells to the common top plate.

8. The nano-engineered anode of claim 7, wherein each unit nano photo cell in the plurality is comprised of:
a first component of conductive or semi conductive crystalline material, forming a backbone which spreads out in a three dimensional structural fashion;
a second component of at least one photo active material bound to the first component; and
a third component of carrier mobility promoter material bound to the second component;
together all of which constitute a framework for separating electrons from holes when a light source is provided to nano engineered anode.

9. The nano-engineered anode of claim 8, wherein the second component of each unit nano photo cell in the plurality acts as a photo active center, converting incoming photons into pairs of electron-holes when a light source is provided to the nano engineered anode.

10. The nano-engineered anode of claim 8, wherein the first component of conductive or semi conductive crystalline material of each unit nano photo cell in the plurality transports electrons from the second component of photo active material or materials to the common bottom plate when a light source is provided to the nano engineered anode.

11. The nano-engineered anode of claim 8 wherein, the first component in each unit nano photo cell in the plurality is further comprise of a photosensitive material which participates in separating electrons from holes in addition to transporting electrons from the second component when a light source is provided to the nano engineered anode.

12. The nano-engineered anode of claim 8, wherein the photo active material for each unit nano photo cell in the plurality includes Fe₂O₃, TiO₂, WO₃, CdS, CdTe, GaAs, InP, CuInSe₂ (copper indium diselenide), CIGS (copper indium gallium diselenide), a-Si, or any combination thereof.

13. The nano-engineered anode of claim 8, wherein the third component of carrier mobility promoter material converts holes from the second component of photo active material or materials into ionic conducting species or charges and transports them to a common top plate when a light source is provided to the nano engineered anode.

14. The nano-engineered anode of claim 8, wherein the third component of carrier mobility promoter material includes a conductive material such as a solid polymer electrolyte (SPE) capable of extracting the holes from the second component and discharging the energy of the holes via a conductive pathway.

15. The nano-engineered anode of claim 8, wherein the material of common bottom plate includes a transparent conductive oxide (TCO) such as indium doped tin oxide (ITO) and fluorine doped tin oxide (FTO), a metal such as Au, Ag, Ni, Ti, and Al, or any combination thereof.

16. The nano-engineered anode of claim 8, wherein the common top plate is comprised of a conductive material such as solid polymer electrolyte capable of extracting the holes from each unit nano photo cell in the plurality and discharging the energy of the holes via the conductivity pathway into water or an electrolyte.

17. A method for constructing a nano-engineered anode comprising the following steps:
preparing a bottom plate;
growing a crystalline structure or backbone on said bottom plate;
generating or enhancing a photoactive material on the crystalline structure or backbone; and
top down carrier promoter capsulation on the photoactive materials of the crystalline framework.

18. The method of claim 17, wherein the step of preparing a bottom plate includes cleaning the surface of a conductive substrate in order to remove any inadequate surface species.

19. The method of claim 17, wherein the step of preparing a bottom plate includes treating the surface of a conductive substrate with a surface preparation process in order to construct a desired surface topography or a seed layer.

20. The method of claim 17, wherein the step of growing a crystalline structure or backbone includes any one of the following:
crystallization in a homogeneous solution via variation of temperature or concentration;
roller coating with a heterogeneous slurry or a colloidal dispersion;
spin-on coating with a heterogeneous slurry or a colloidal dispersion;
spray vaporization using dissolved salts;
spray pyrolysis using dissolved salts;
chemical vapor deposition (CVD);
physical vapor deposition (PVD); or
electroplating.

21. The method of claim 17, wherein the step of generating or enhancing the photoactive material on the crystalline structure includes any one of the following:
deposition using vaporization of a homogeneous solution containing desired reactive reagents;
reactive removal of surface materials;
reactive doping and implantation;
reactive surface binding with a solution containing reacting reagents;
spray vaporization using dissolved salts;
spray pyrolysis using dissolved salts;
chemical vapor deposition (CVD);
physical vapor deposition (PVD);
inert atmosphere annealing, baking, and heating; or
reactive annealing, baking, and heating using reactive gases.

22. The method of claim 17, wherein the step of top down carrier promoter capsulation is accomplished via any one of the following processes:
a dry coating process with a melted solid electrolyte or molten salt at an elevated temperature;
a condensation process under low vapor pressure of a selected precursor;
a surface binding process by adding a solution of a selected precursor followed by a vaporization, or a concentration, or a curing, or an annealing, or a drying process or a combination of selective processes aforementioned;
chemical vapor deposition (CVD); or
physical vapor deposition (PVD).

23. A PEC cell comprising:
a nano-engineered anode,
a cathode,
water or an electrolyte, and
a zone separator which prevents hydrogen and oxygen from mixing,
wherein electrons and holes from the nano-engineered anode move into two separate flow directions whenever a light source and an adequate external field such as an electrical field, a magnetic field, an electromagnetic field or a combination of the fields, are applied to the PEC cell, thereby minimizing electron-hole recombination and promoting field modulated multiple exciton generations.

24. The PEC cell of claim 23, wherein the nano engineered anode is comprised of:
a plurality of unit nano photo cells joined together and forming a nano structured framework, each unit nano photo cell in the plurality sharing a pathway to an ionic conductive common top plate coupled to the nano structure framework; and
a conductive common bottom plate coupled with the nano structured framework;
wherein the common top plate discharges the energy of the holes from each of the unit nano photo cell in the plurality into water or an aqueous electrolyte, thereby generating oxygen or hydrogen peroxide or a combination of oxygen and hydrogen peroxide whenever a light source is applied to the PEC cell.

25. The PEC cell of claim 24 further wherein electrons from the plurality of unit nano photo cells flow through the common bottom plate and feed into the cathode where water is reduced to form hydrogen gas.

26. The PEC cell of claim 24, wherein each unit nano photo cell in the plurality is comprised of:
a first component of conductive or semi conductive crystalline material, forming a backbone which spreads out in a three dimensional structural fashion;
a second component of at least one photo active material bound to the first component; and
a third component of carrier mobility promoter material bound to the second component;
together all of which constitute a framework for separating electrons from holes.

27. The PEC cell of claim 26, wherein the second component of each unit nano photo cell in the plurality acts as a photo active center, converting incoming photons into pairs of electron-holes when a light source is provided to the PEC cell.

28. The PEC cell of claim 26, wherein the first component of each unit nano photo cell in the plurality transports electrons from the second component of photo active material or materials to the common bottom plate when a light source is provided to the PEC cell.

29. The PEC cell of claim 26, wherein, the first component of each unit nano photo cell is further comprised of a photosensitive material which participates in separating electrons from holes when a light source is provided to the PEC cell.

30. The PEC cell of claim 26, wherein the third component of each unit nano photo cell in the plurality converts holes from the second component of photo active material or materials into ionic conducting species or charges and transports them to the common top plate when a light source is provided to the PEC cell.

31. The PEC cell of claim 26, wherein the cathode is composed of a metallic material selected from the following: platinum, palladium, rhodium, iridium, ruthenium, osmium, nickel, silver, or any combination thereof.

32. The PEC cell of claim 26, wherein the zone separator is a water permissive material preventing hydrogen and oxygen from mixing and allows a distance between the cathode and the anode to be suitable for static liquid phase operation or flow dynamic operation passing liquid component through the PEC cell.

33. The PEC cell of claim 32, wherein the preferred gap distance is in the range from 10 nm to 50 μm.

34. A PEC cell comprising:
a nano-engineered anode,
an internal photovoltaic component for generating an internal bias voltage,
a cathode bound to the internal photovoltaic component
water or an electrolyte, and
a zone separator which prevents hydrogen and oxygen from mixing,
wherein electrons and holes from the nano-engineered anode move into two separate flow directions whenever a light source and an adequate internal field such as an electrical field, a magnetic field, an electromagnetic field or a combination of the fields, are applied to the PEC cell, thereby minimizing electron-hole recombination and promoting field modulated multiple exciton generations.

35. The PEC cell of claim 34, wherein the nano engineered anode is comprised of:
a plurality of unit nano photo cells joined together and forming a nano structured framework where each unit nano photo cell in the plurality sharing a common conductive pathway:
an ionic conductive common top plate coupled with the nano structured framework; and
a conductive common bottom plate coupled with the nano structured framework and bound to the internal photovoltaic component
wherein the common top plate discharges the energy of the holes from the plurality of unit nano photo cells into water and generates oxygen or hydrogen peroxide or a combination of oxygen and hydrogen peroxide, and further wherein electrons from the plurality of unit nano photo cells flow through both the common bottom plate of the anode and the internal photovoltaic component, generating hydrogen on the cathode side of the PEC cell.

36. The PEC cell of claim 35, wherein each unit nano photo cell in the plurality is comprised of:
a first component of conductive or semi conductive crystalline material, forming a backbone which spreads out in a three dimensional structural fashion;
a second component of at least one photo active material bound to the first component; and
a third component of carrier mobility promoter material bound to the second component;
together all of which constitute a framework for separating electrons from holes.

37. The PEC cell of claim 36, wherein the second component acts as a photo active center, converting incoming photons into pairs of electron-holes when a light source is provided to the PEC cell.

38. The PEC cell of claim 36, wherein the first component of conductive or semi conductive crystalline material transports electrons from the second component of photo active material or materials to a common bottom plate when a light source is provided to the PEC cell.

39. The PEC cell of claim 36, wherein the third component of carrier mobility promoter material converts holes from the second component of photo active material or materials into ionic conducting species or charges and transports them to a common top plate when a light source is provided to the PEC cell.

40. The PEC cell of claim 36, wherein the internal photovoltaic component is comprised of a film stack integrating at least one of the following photovoltaic types: copper indium diselenide (CuInSe₂), copper indium gallium diselenide (CIGS), amorphous silicon (a-Si), compound of group III-V (GaAs, InP etc), cadmium telluride (CdTe), crystalline silicon (c-Si), thin film silicon (thin-Si).

41. A nano-engineered electrode for use in a photovoltaic cell comprising:
a plurality of unit nano photo cells joined together and forming a nano structured framework;
a conductive common top plate coupled to the nano structured framework; and
a conductive common bottom plate coupled to the nano structured framework,
thereby forming a photo active mass in a 3D lattice fashion or a hybrid crystalline structure, transporting electrons from photo active centers to the common bottom plate and transporting the holes to the common top plate;
wherein electrons and holes from the nano-engineered electrode move into two separate flow directions when a light source and an adequate field such as an electrical field, a magnetic field, an electromagnetic field or a combination of the fields are applied, thereby minimizing electron-hole recombination and promoting field modulated multiple exciton generations.

42. The photovoltaic cell of claim 41, wherein each unit nano photo cell in the plurality is comprised of:
a first component of conductive or semi conductive crystalline material, forming a backbone which spreads out in a three dimensional structural fashion;
a second component of at least one photo active material bound to the first component; and
a third component of carrier mobility promoter material bound to the second component;
together all of which constitute a framework for separating electrons from holes when a light source is provided to the photovoltaic cell.

43. The photovoltaic cell of claim 42, wherein the second component is comprised of a photosensitive material or materials forming at least one junction with the first component such that the second component acts as a photo active center, converting incoming photons into pairs of electron-holes when a light source is provided to the photovoltaic cell.

44. The photovoltaic cell of claim 42, wherein the first component of conductive or semi conductive crystalline material transports electrons from the second component of at least one photo active material to a common bottom plate when a light source is provided to the photovoltaic cell.

45. The photovoltaic cell of claim 42, wherein, the first component of conductive or semi conductive crystalline material is further comprised of a photosensitive material which participates in separating electrons from holes in addition to transporting electrons from the second component when a light source is provided to the photovoltaic cell.

46. The photovoltaic cell of claim 41, wherein the photo active material of each unit nano photo cell in the plurality is selected from Fe₂O₃, TiO₂, WO₃, CdS, CdTe, GaAs, InP, CuInSe₂, CIGS, a-Si, Si-Ge, or any combination thereof.

47. The photovoltaic cell of claim 42, wherein the third component of conductive carrier mobility promoter material extracts holes from the second component of photo active material or materials and transports them to a common top plate when a light source is provided to the photovoltaic cell.

48. A sensor comprising:
a nano-engineered anode,
a cathode, and
water or an aqueous electrolyte or a non-aqueous electrolyte containing a reduction/oxidation couple
wherein electrons and holes from the nano-engineered anode move into two separate flow directions when a light source and an adequate external field such as an electrical field, a magnetic field, an electromagnetic field or a combination of the fields are applied, thereby minimizing electron-hole recombination and promoting field modulated multiple exciton generations.

49. The sensor of claim 48, wherein the nano engineered anode is comprised of:
a plurality of unit nano photo cells joined together and forming a nano crystalline framework where each unit nano photo cell shares a pathway to:
an ionic conductive common top plate coupled with the nano crystalline framework; and
a conductive common bottom plate coupled with the nano crystalline framework.
wherein the common top plate discharges the energy of the holes from the plurality of unit nano photo cells into water or a chemical in order to produce an oxidation reaction, and further wherein electrons from the plurality of unit nano photo cells flow through the common bottom plate and feed into the cathode where water or a chemical is reduced.

50. The sensor of claim 49, wherein each unit nano photo cell in the plurality is comprised of:
a first component of conductive or semi conductive crystalline material, forming a backbone which spreads out in a three dimensional structural fashion;
a second component of at least one photo active material bound to the first component; and
a third component of carrier mobility promoter material bound to the second component;
together all of which constitute a framework for separating electrons from holes.

51. The sensor of claim 50, wherein the second component acts as a photo active center, converting incoming photons into pairs of electron-holes when a light source is provided to the sensor.

52. The sensor of claim 50, wherein the first component of conductive or semi conductive crystalline material transports electrons from the second component of photo active material or materials to a common bottom plate when a light source is provided to the sensor.

53. The sensor of claim 50, wherein, the first component is further comprised of a photosensitive material such that the first component in each unit nano photo cell also participates in separating electrons from holes in addition to transporting electrons from the second component when a light source is provided to the sensor.

54. The sensor of claim 50, wherein the third component of carrier mobility promoter material converts holes from the second component of photo active material or materials into ionic conducting species or charges and transports them to a common top plate when a light source is provided to the sensor.

55. The sensor of claim 50, wherein the distance between the cathode and the anode is in the range from 10 nm to 50 μm.

56. The sensor of claim 50, wherein the cathode is composed of a metallic material selected from the following: platinum, palladium, rhodium, iridium, ruthenium, osmium, nickel, silver, or any combination thereof.
